(19) United States
(12) Patent Application Publication
(10) Pub. No.: US 2024/0141547 A1
(43) Pub. Date: May 2, 2024

(54) PREPARATION METHOD OF P-TYPE HIGH-RESISTANCE AND ULTRA-HIGH-RESISTANCE CZOCHRALSKI MONOCRYSTALLINE SILICON SUBSTRATE

(71) Applicant: SHANGHAI INSTITUTE OF MICROSYSTEM AND INFORMATION TECHNOLOGY CHINESE ACADEMY OF SCIENCES, Shanghai (CN)

(72) Inventors: Xing Wei, Shanghai (CN); Ming Hao Li, Shanghai (CN); Rong Wang Dai, Shanghai (CN); Zi Wen Wang, Shanghai (CN); Zhong Ying Xue, Shanghai (CN)

(73) Assignee: SHANGHAI INSTITUTE OF MICROSYSTEM AND INFORMATION TECHNOLOGY CHINESE ACADEMY OF SCIENCES, Shanghai (CN)

(21) Appl. No.: 18/177,724

(22) Filed: Mar. 2, 2023

(30) Foreign Application Priority Data
Nov. 2, 2022 (CN) 202211360231.4

(51) Int. Cl. C30B 15/20; C30B 29/06

(52) U.S. Cl. CPC C30B 15/20; C30B 29/06

(57) ABSTRACT

The present invention relates to a preparation method of a P-type high-resistance and ultra-high-resistance Czochralski monocrystalline silicon substrate. According to the present invention, an oxygen concentration in a silicon wafer is controlled to match with a resistivity, so as to realize that a conductive type of the silicon substrate does not change after a device is manufactured, and that the silicon substrate has a high resistivity. The oxygen concentration and the resistivity in silicon crystal can be adjusted separately or together; and operation is flexible, and a yield of a high-resistance silicon crystal is greatly improved.

### CROSS-REFERENCE TO RELATED APPLICATION

This application claims the priority benefit of Chinese application serial no. 202211360231.4, filed on Nov. 2, 2022. The entirety of the above-mentioned patent application is hereby incorporated by reference herein and made a part of this specification.

### BACKGROUND

### Technical Field

The present invention belongs to the field of semiconductors, and particularly relates to a preparation method of a P-type high-resistance and ultra-high-resistance Czochralski monocrystalline silicon substrate.

### Description of Related Art

Czochralski grown monocrystalline silicon wafers are widely used to manufacture semiconductor electronic devices, and different devices have different requirements for oxygen concentration and resistivity in the silicon wafers. The demand of radio frequency SOI for P-type high-resistance monocrystalline silicon is increasing. The radio frequency SOI (RF-SOI) is a radio-frequency device and integrated circuit made by an SOI technology. SOI refers to a bottom-resistant structure in which a SiO₂ insulating layer is inserted into a bulk silicon material. Fabrication of low-voltage and low-power integrated circuits on an SOI substrate is one of the main choices of deep submicron technology nodes. The RF-SOI has the following advantages: (1) the RF-SOI has excellent performance at very high working frequency; (2) the RF-SOI can realize an integrated circuit stack structure, and improve a power and energy efficiency ratio at the same time; and (3) an SOI substrate adopted in the RF-SOI process can reduce a parasitic effect, so that a quality factor of a radio-frequency chip is higher, the loss is lower, a noise coefficient is better, and meanwhile, an insulation level and a linearity of products are also improved.

In a manufacturing process of the Czochralski monocrystalline silicon, polycrystalline silicon raw materials are transferred into a quartz crucible, heated and melted, then seed crystal is dipped into a silicon melt liquid and rotated upward for pulling, the silicon at an interface between the seed crystal and the silicon melt liquid is solidified and crystallized, and as the seed crystal is pulled upward, a monocrystalline silicon ingot is formed.

A resistivity and a conductive type of the monocrystalline silicon are determined by a type and a concentration of doped electrically active impurities (B, P, As, etc.). During the growth of the Czochralski monocrystalline silicon, oxygen is transported into a silicon melt through dissolution in the quartz crucible, and the silicon dioxide (SiO₂) in the crucible is changed into movable silicon and oxygen atoms or loosely-bonded silicon and oxygen or SiO. Most of the oxygen dissolved in the silicon melt is evaporated from a free surface of the melt, and the remaining oxygen enters the growing crystal by segregation through a solid-liquid interface between the melt and the crystal. An oxygen-related thermal donor generated during low-temperature heat treatment may seriously affect the resistivity and the conductive type of the silicon wafers.

Impurity compensation can change the conductive type of a certain region in the semiconductor by diffusion or ion implantation as required, so as to fabricate various devices. However, a phenomenon of N_{D}≈N_{A} may occur if the control is not correct. At this time, donor electrons can just fill an acceptor energy level. Although there are many impurities, electrons and holes cannot be provided for a guide band and a valence band. This material is easily mistaken for a high-purity semiconductor. In fact, it has many impurities and poor performance, so it cannot be used in practice.

The prior art mainly reduces the generation of the thermal donor by reducing the oxygen concentration in silicon crystals, thereby reducing the impact of the thermal donor on the resistivity. Due to the use of the crucible, it is difficult to reduce the oxygen in the silicon crystals and has requirements for a doping technology.

### SUMMARY

A technical problem to be solved by the present invention is to provide a preparation method of a P-type high-resistance and ultra-high-resistance Czochralski monocrystalline silicon substrate. According to the method, an oxygen concentration in a silicon wafer is controlled to match with a resistivity, so as to realize that a conductive type of the silicon substrate does not change after a device is manufactured, and the silicon substrate has a high resistivity.

The present invention provides a preparation method of a P-type high-resistance and ultra-high-resistance Czochralski monocrystalline silicon substrate, including the following steps:

(1) calculating a generated thermal donor concentration n_{TD} through change of a resistivity of a silicon wafer before and after treatment and according to a conversion relationship between a boron impurity concentration and the resistivity in SEMI MF723-99 standard; converting a compensated acceptor concentration 2n_{TD} into a P-type resistivity ρ₀, wherein ρ₀ is a critical value of the resistivity, an initial resistivity of the P-type silicon wafer should lower than ρ₀, otherwise, the conductive type of the substrate after heat treatment may be converted into an N type;

(2) taking silicon wafers with different oxygen concentrations [Oᵢ]₀ for heat treatment experiments to obtain a relationship between the thermal donor concentration n_{TD} and the oxygen concentration, so as to draw a relationship curve between the oxygen concentration in a silicon crystal and the critical value of the resistivity, and obtaining a matching value of any oxygen concentration and the resistivity by fitting according to the curve; and

(3) preparing high-resistance and ultra-high-resistance monocrystalline silicon with a P-type substrate by controlling process parameters according to the matching value of the oxygen concentration and the resistivity.

The heat treatment in steps (1) and (2) is performed at a temperature of 250-550° C. for a duration of 0.5-5 h.

2n_{TD} and ρ₀ refer to the conversion relationship between the boron impurity concentration and the resistivity in SEMI MF723-99 standard.

In the SEMI MF723-99 standard, a boron-doped silicon single crystal calculates a dopant concentration value from a resistivity value, that is, a formula from the P-type resistivity to the concentration as follows:

$$N = \frac{1.33 \times {10}^{16}}{ρ} + \frac{1.082 \times {10}^{17}}{ρ ( 1 + {( 54.56 ρ )}^{1.105} )}$$

where, ρ-resistivity, Ω·cm; and N-dopant concentration, atoms/cm³.

The resistivity value of the boron-doped silicon single crystal is calculated based on the dopant concentration value, that is, a formula from the P-type concentration to the resistivity as follows:

$$ρ = \frac{1.305 \times {10}^{16}}{N} + \frac{1.133 \times {10}^{17}}{N ( 1 + {( 2.58 \times {10}^{- 19} N )}^{- 0.737} )}$$

where, ρ-resistivity, Ω·cm; and N-dopant concentration, atoms/cm³.

The high resistance refers to >1000 ohm-cm, and the ultra-high resistance refers to >10000 ohm-cm.

The monocrystalline silicon substrate may have a high or ultra-high resistivity within a range of a high oxygen concentration, which meets requirements of an RFSOI substrate.

### Beneficial Effects

According to the present invention, the oxygen concentration in the silicon wafer is controlled to match with the resistivity, so as to realize that the conductive type of the silicon substrate does not change after the device is manufactured, and that the silicon substrate has a high resistivity. The oxygen concentration and the resistivity in silicon crystal can be adjusted separately or together; and operation is flexible, and a yield of a high-resistance silicon crystal and an ultra-high-resistance silicon crystal is greatly improved.

### BRIEF DESCRIPTION OF THE DRAWINGS

FIG. 1 is a schematic diagram of growth of a crystal of the present invention.

FIG. 2 is a resistivity relationship to be met by P-type high-resistance silicon crystals with different oxygen concentrations.

FIG. 3 is a calculation process of an oxygen concentration and a resistivity.

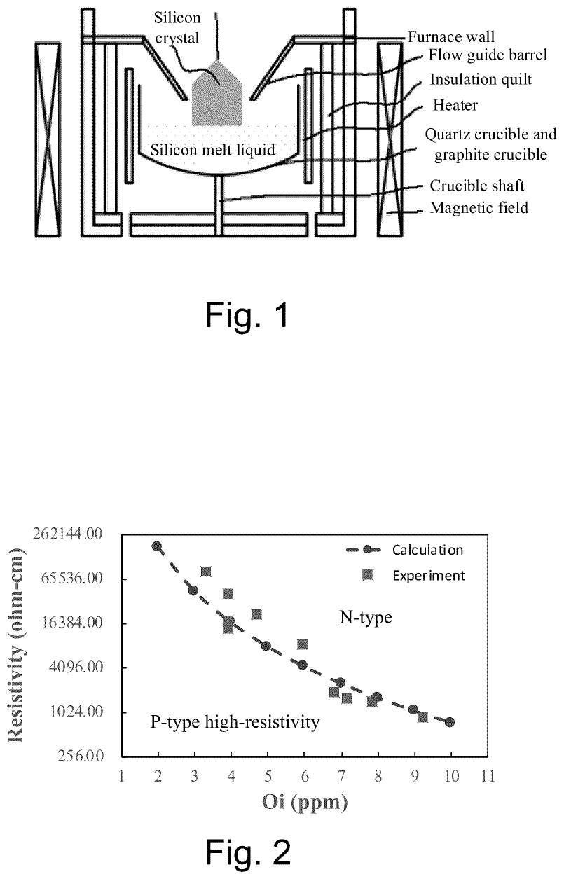

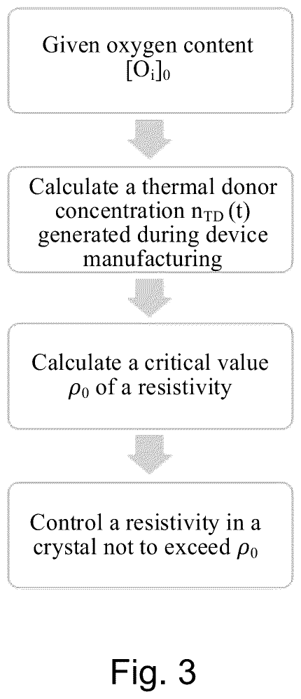

### DESCRIPTION OF THE EMBODIMENTS

The present invention is further described below in conjunction with specific embodiments. It should be understood that these embodiments are only used to explain the present invention and not to limit the scope of the present invention. In addition, it should be understood that those skilled in the art can make various changes or modifications to the present invention after reading concentrations taught in the present invention. These equivalent forms also fall within the scope defined in the claims attached to the present application.

### Embodiment 1

Taking heat treatment at 450° C. for 2 h as an example:
(1) a generated thermal donor concentration n_{TD} is calculated through change of a resistivity of a silicon wafer before and after heat treatment according to a conversion relationship between a boron impurity concentration and the resistivity, and since thermal donors are double donors, that is, the donor concentration provided by the thermal donors is 2n_{TD}, a compensated acceptor concentration 2n_{TD} is converted into a P-type resistivity ρ₀. ρ₀ is a critical value of the resistivity, and in order to make the P-type silicon wafer with an oxygen concentration [Oᵢ]₀ not reverse and have a high or ultra-high resistivity after device manufacturing, an initial resistivity of the P-type silicon wafer should lower than ρ₀;
(2) silicon wafers with different oxygen concentrations [Oᵢ]₀ are taken for heat treatment experiments to obtain a relationship between the thermal donor concentration n_{TD} and the oxygen concentration, so as to draw a relationship curve between the oxygen concentration in a silicon crystal and the critical value of the resistivity (as shown in FIG. 2), and a matching value of any oxygen concentration and the resistivity is obtained by fitting according to the curve; and
(3) high-resistance monocrystalline silicon with a P-type substrate is prepared by controlling process parameters according to the matching value of the oxygen concentration and the resistivity.

According to the relationship between the oxygen concentration and the critical resistivity obtained in step (1) and step (2), if the oxygen concentration is certain (6 ppm), in order to obtain the high-resistance silicon wafer with the substrate still being the P type after device manufacturing, a target resistivity for growth of the monocrystalline silicon should lower than 4096 ohm-cm. If the resistivity of the P-type silicon wafer is determined to be 16384 ohm-cm, the oxygen concentration in the silicon wafer shall be controlled at 4 ppm.

What is claimed is:

1. A preparation method of a P-type high-resistance and ultra-high-resistance Czochralski monocrystalline silicon substrate, comprising the following steps:
step (1) calculating a generated thermal donor concentration n_{TD} through change of a resistivity of a silicon wafer before and after heat treatment and according to a conversion relationship between a boron impurity concentration and the resistivity, wherein thermal donors are double donors, so a compensated acceptor concentration is 2n_{TD}, the compensated acceptor concentration is 2n_{TD} and is converted into a P-type resistivity ρ₀, ρ₀ is a critical value of the resistivity, and an initial resistivity of the P-type silicon wafer should lower than ρ₀;
step (2) taking silicon wafers with different oxygen concentrations [Oᵢ]₀ for heat treatment experiments to obtain a relationship between the thermal donor concentration n_{TD} and the oxygen concentration, so as to draw a relationship curve between the oxygen concentration in a silicon crystal and the critical value of the resistivity, and obtaining a matching value of any oxygen concentration and the resistivity by fitting according to the curve; and
step (3) preparing high-resistance and ultra-high-resistance monocrystalline silicon with a P-type substrate by controlling process parameters according to the matching value of the oxygen concentration and the resistivity.

2. The preparation method of claim 1, wherein the heat treatment in step (1) and step (2) is performed at a temperature of 250-550° C. for a duration of 0.1-8 h.

3. The preparation method of claim 1, wherein 2n_{TD} and ρ₀ refer to the conversion relationship between the boron impurity concentration and the resistivity in SEMI MF723-99 standard.

4. The preparation method of claim 1, wherein the high resistance refers to >1000 ohm-cm.

5. The preparation method of claim 1, wherein the ultra-high resistance refers to >10000 ohm-cm.
